(19) United States
(12) Patent Application Publication
(10) Pub. No.: US 2018/0122970 A1
(43) Pub. Date: May 3, 2018

(54) LIGHT DETECTION DEVICE

(71) Applicant: SEOUL VIOSYS CO., LTD., Ansan-si (KR)

(72) Inventors: Ki Yon Park, Ansan-si (KR); Gun Woo Han, Ansan-si (KR); Choong Min Lee, Ansan-si (KR); Soo Hyun Lee, Ansan-si (KR)

(21) Appl. No.: 15/575,752

(22) PCT Filed: May 11, 2016
(86) PCT No.: PCT/KR2016/004900

§ 371 Date: Nov. 20, 2017

(30) Foreign Application Priority Data
May 18, 2015 (KR) 10-2015-0068990
Jul. 20, 2015 (KR) 10-2015-0102370

(51) Int. Cl. H01L 31/0304; H01L 31/108; H01L 31/18

(52) U.S. Cl. CPC H01L 31/03044; H01L 31/03042; H01L 31/1848; H01L 31/1852; H01L 31/1892; H01L 31/108

(57) ABSTRACT

Disclosed herein is a light detection device. The light detection device includes a base layer, an electrostatic discharge (ESD) prevention layer disposed on the base layer and including an undoped nitride-based semiconductor, a light absorption layer disposed on the ESD prevention layer, a Schottky junction layer disposed on the light absorption layer, and a first electrode and a second electrode electrically connected to the Schottky junction layer and the base layer, respectively, wherein the ESD prevention layer has a lower average n-type dopant concentration than the base layer.

### TECHNICAL FIELD

Exemplary embodiments of the present disclosure relate to a light detection device, and more particularly, to a semiconductor light detection device having high detection efficiency with respect to light in a UV wavelength band and having improved electrostatic discharge resistance.

### BACKGROUND ART

A semiconductor light detection device is a semiconductor device configured to operate based on a principle of allowing electric current to flow upon application of light. Particularly, semiconductor light detection devices capable of detecting UV light can be applied to various fields including commerce, medicine, military and communication industries, and thus occupy an important position in the related art. Semiconductor light detection devices are developed based on the principle that a depletion region is generated due to separation of electrons and holes in a semiconductor by irradiation with light and electric current is generated by flow of electrons generated in the semiconductor.

Conventionally, semiconductor light detection devices using silicon are used. However, the semiconductor light detection devices using silicon require application of high voltage for operation and have low detection efficiency. Particularly, a semiconductor light detection device configured to detect UV light and formed of silicon has low light detection efficiency due to characteristics of silicon exhibiting high sensitivity with respect to not only UV light but also visible light and infrared light. In addition, the UV light detection device formed of silicon exhibits thermal and chemical instability.

On the other hand, a light detection device using a nitride-based semiconductor has higher reactivity, higher response speed, lower noise level and higher thermal and chemical stability than the light detection device using silicon. Particularly, a light detection device using an AlGaN layer as a light absorption layer exhibits good characteristics as a UV light detection device. Such nitride-based semiconductor light detection devices are fabricated in various structures, for example, a photoconductor, a Schottky junction light detection device, a p-i-n type light detection device, and the like.

The p-i-n light detection device has a drawback of significant deterioration in characteristics as an optical device due to severe light loss during transmission of light to be detected through a p-type semiconductor layer. The Schottky junction light detection device allows light to enter a light absorption layer after passing through a thin Ni layer, which acts as a current spreading layer, thereby providing good uniformity of characteristics and good light extraction efficiency.

In general, the Schottky junction light detection device includes a substrate, a buffer layer disposed on the substrate, a light absorption layer disposed on the buffer layer, and a Schottky junction layer disposed on the light absorption layer. Further, a first electrode and a second electrode are formed on the Schottky junction layer and the buffer layer or the light absorption layer, respectively. In order for the Schottky junction light detection device to be used as a UV light detection device, the light absorption layer is formed of a nitride-based semiconductor having an energy band gap capable of absorbing UV light. Accordingly, AlGaN is mainly used as a semiconductor material constituting the light absorption layer. In addition, a GaN layer is generally used as the buffer layer.

Moreover, a GaN layer, InGaN layer and an AlGaN layer used as light absorption layers in a typical gallium nitride semiconductor light detection device have inherent defects, which cause current flow in the light detection device in response to not only UV light but also visible light. For responsivity, such a semiconductor light detection device has a UV-to-visible rejection ratio of about 10³. Namely, the typical semiconductor light detection device allows current flow through reaction with not only UV light but also visible light, thereby providing low detection accuracy.

Moreover, despite advantages of easy fabrication and high efficiency due to a relatively simple structure, the Schottky junction light detection device does not have a sufficiently thick depletion region due to an insufficient Schottky barrier resulting from a small band gap difference between the Schottky junction layer and the light absorption layer and is very vulnerable to electrostatic discharge. Accordingly, the Schottky junction light detection device can suffer from failure due to electrostatic discharge and has problems of low reliability and deterioration in light detection accuracy over time.

### DISCLOSURE

### Technical Problem

Exemplary embodiments of the present disclosure are directed to providing a light detection device that has high light detection efficiency with respect to light in a wavelength band to be detected, particularly, UV light, more particularly, UV light in the UVC band.

Exemplary embodiments of the present disclosure are directed to providing a method of fabricating a light detection device that includes a light absorption layer having good crystallinity and exhibits high light detection efficiency with respect to UV light.

Exemplary embodiments of the present disclosure are directed to providing a light detection device that has good electrostatic discharge resistance, thereby securing good reliability.

It should be understood that the above objects are provided for illustration only and the present disclosure is not limited thereto.

### Technical Solution

In accordance with one aspect of the present disclosure, a light detection device includes: a base layer; an electrostatic discharge (ESD) prevention layer disposed on the base layer and including an undoped nitride-based semiconductor; a light absorption layer disposed on the ESD prevention layer; a Schottky junction layer disposed on the light absorption layer; and a first electrode and a second electrode electrically connected to the Schottky junction layer and the base layer, respectively, wherein the ESD prevention layer has a lower average n-type dopant concentration than the base layer.

In accordance with another aspect of the present disclosure, a light detection device includes: a base layer including a nitride-based semiconductor; an ESD prevention layer disposed on the base layer; a light absorption layer disposed on the ESD prevention layer and including an Al-containing nitride-based semiconductor; and a Schottky junction layer disposed on the light absorption layer, wherein the ESD prevention layer includes a first nitride layer disposed on the base layer and including a nitride-based semiconductor having an Al composition ratio of 0.9 or more, and a second nitride layer disposed on the first nitride layer and including a nitride-based semiconductor having a lower Al composition ratio than the first nitride layer, the first nitride layer including at least one pit formed on an upper portion thereof, the second nitride layer filling the at least one pit.

In accordance with a further aspect of the present disclosure, a light detection device includes: a base layer including a nitride-based semiconductor; an ESD prevention layer disposed on the base layer; a light absorption layer disposed on the second nitride layer and an Al-containing nitride-based semiconductor; and a Schottky junction layer disposed on the light absorption layer, wherein the ESD prevention layer includes a first nitride layer disposed on the base layer and including a nitride-based semiconductor having an Al composition ratio of 0.9 or more, and a second nitride layer disposed on the first nitride layer and including a nitride-based semiconductor having a lower Al composition ratio than the first nitride layer, the first nitride layer including at least one pit formed on an upper portion thereof, the first nitride layer having a higher defect density than the second nitride layer.

In accordance with yet another aspect of the present disclosure, a method of fabricating a light detection device includes: forming a base layer including a nitride-based semiconductor on a substrate; forming a first nitride layer including a nitride-based semiconductor having an Al composition ratio of 0.9 or more on the base layer, the first nitride layer including at least one pit; forming a second nitride layer including a nitride-based semiconductor having a lower Al composition ratio than the first nitride layer on the first nitride layer; forming a light absorption layer including an Al-containing nitride-based semiconductor on the second nitride layer; and forming a Schottky junction layer on the light absorption layer.

### Advantageous Effects

Exemplary embodiments can provide a light detection device including a low current blocking layer and exhibiting low reactivity with respect to visible light. With this structure, the light detection device can have a high UV-to-visible light rejection ratio, high light detection efficiency and reliability.

In addition, according to exemplary embodiments, the method of fabricating a light detection device can provide a light detection device including a light absorption layer having improved crystallinity and capable of preventing a flow of minute current through reaction with visible light.

Furthermore, according to exemplary embodiments, the detection device includes an ESD prevention layer, thereby improving electrostatic discharge characteristics. Particularly, exemplary embodiments of the present disclosure can provide a light detection device having a Schottky junction structure while securing excellent electrostatic discharge resistance.

Furthermore, according to exemplary embodiments, high electric current generated in the light detection device due to electrostatic discharge can easily flow through pits and/or a defect concentrated portion, thereby providing good electrostatic discharge resistance.

### DESCRIPTION OF DRAWINGS

FIG. 1 is a sectional view of a light detection device according to one exemplary embodiment of the present disclosure.

FIG. 2 is a sectional view of a light detection device according to another exemplary embodiment of the present disclosure.

FIG. 3a and FIG. 3b are an enlarged view and a graph depicting an ESD prevention layer of the light detection device according to another exemplary embodiment of the present disclosure.

FIG. 4a and FIG. 4b are an enlarged view and a graph depicting an ESD prevention layer of the light detection device according to a further exemplary embodiment of the present disclosure.

FIG. 5 is a graph comparing characteristics of light detection devices prepared in Experimental Example.

FIG. 6 is a sectional view of a light detection device according to yet another exemplary embodiment of the present disclosure.

FIG. 7 is a sectional view of a light detection device according to yet another exemplary embodiment of the present disclosure.

FIG. 8 and FIG. 9 are sectional views illustrating a method of separating a light detection device from a growth substrate according to exemplary embodiments of the present disclosure.

FIG. 10a and FIG. 10b are a graph and a transmission electron micrograph (TEM) illustrating a low current blocking layer of the light detection device according to the exemplary embodiment of the present disclosure.

FIG. 11 to FIG. 18 are sectional views and enlarged sectional views of a light detection device according to yet another exemplary embodiment of the present disclosure and a method of fabricating the same.

FIG. 19 is a graph depicting a growth method of a second nitride layer of the light detection device according to the exemplary embodiment of the present disclosure.

FIG. 20 to FIG. 22 are sectional views of a light detection device according to yet another exemplary embodiment of the present disclosure and a method of fabricating the same.

FIG. 23 to FIG. 25 are sectional views of a light detection device according to yet another exemplary embodiment of the present disclosure and a method of fabricating the same.

### MODE FOR INVENTION

Light detection devices according to various exemplary embodiments and a method of fabricating the same may be realized in various aspects.

According to some exemplary embodiments, a light detection device may include: a base layer; an electrostatic discharge (ESD) prevention layer disposed on the base layer and including an undoped nitride-based semiconductor; a light absorption layer disposed on the ESD prevention layer; a Schottky junction layer disposed on the light absorption layer; and a first electrode and a second electrode electrically connected to the Schottky junction layer and the base layer, respectively, wherein the ESD prevention layer has a lower average n-type dopant concentration than the base layer.

The ESD prevention layer may include at least one undoped nitride-based semiconductor layer, and the at least one undoped nitride-based semiconductor layer may have a total thickness of 300 nm to 400 nm.

The light detection device may further include a low current blocking layer disposed between the ESD prevention layer and the light absorption layer and including a multilayer structure layer.

An interface between layers of the multilayer structure layer may have a greater band gap than each of the layers of the multilayer structure layer.

The ESD prevention layer may include a doped layer including an n-type dopant.

The doped region may include a first doped region, a second doped region disposed on the first doped region, and a third doped region disposed on the second doped region, the second doped region may have a higher doping concentration than the first doped region, and the third doped region may have a higher doping concentration than the second doped region.

The first doped region may adjoin the second doped region and the second doped region may adjoin the third doped region.

The concentration of the n-type dopant in at least one of the first to third doped regions may have a gradually increasing or decreasing profile towards the light absorption layer, or a modulation doped profile.

The doped region may include at least one n-type dopant shock region.

The undoped nitride-based semiconductor may be placed on an upper surface and a lower surface of the doped region.

The undoped nitride-based semiconductor of the ESD prevention layer may adjoin at least one of the low current blocking layer and the base layer.

The light absorption layer may include at least one of AlGaN and AlInGaN.

The multilayer structure layer of the low current blocking layer may include a super lattice structure in which AlₓGa₍₁₋ₓ₎N layers and Al_{y}Ga_{(1-y)}N layers (x≠y) are repeatedly stacked one above another.

The low current blocking layer may have a higher defect density than the light absorption layer.

The light detection device may further include a substrate disposed under the base layer, wherein the first electrode is placed on the Schottky junction layer and the second electrode is placed on the base layer to be electrically connected thereto.

The light detection device may have a structure flip-bonded to a secondary substrate such that the light absorption layer is directed towards a lower surface of the light detection device.

The light absorption layer may be disposed to be directed towards the lower surface of the light detection device, the first electrode may be disposed under a lower surface of the Schottky junction layer, and the second electrode may be disposed on an upper surface of the base layer.

The base layer may have a greater energy band gap than the light absorption layer.

The base layer may have a greater energy band gap than the light absorption layer.

According to some exemplary embodiments, a light detection device may include: a base layer including a nitride-based semiconductor; an ESD prevention layer disposed on the base layer; a light absorption layer disposed on the ESD prevention layer and including an Al-containing nitride-based semiconductor; and a Schottky junction layer disposed on the light absorption layer, wherein the ESD prevention layer includes a first nitride layer disposed on the base layer and including a nitride-based semiconductor having an Al composition ratio of 0.9 or more, and a second nitride layer disposed on the first nitride layer and including a nitride-based semiconductor having a lower Al composition ratio than the first nitride layer, the first nitride layer includes at least one pit formed on an upper portion thereof, and the second nitride layer fills the at least one pit.

The light absorption layer may include AlGaN having an Al composition ratio of 0.28 or more.

The light absorption layer may include AlGaN having an Al composition ratio of 0.4 or more.

The second nitride layer may include a defect concentrated portion extending from the at least one pit.

The first nitride layer may be formed of MN and the second nitride layer may be formed of AlGaN.

The base layer may include a GaN layer.

The light detection device may further include a low current blocking layer disposed between the second nitride layer and the light absorption layer, and including a multilayer structure layer.

The light detection device may further include a first electrode and a second electrode electrically connected to the base layer and the Schottky junction layer, respectively.

According to some exemplary embodiments, a light detection device may include: a base layer including a nitride-based semiconductor; an ESD prevention layer disposed on the base layer; a light absorption layer disposed on the second nitride layer and an Al-containing nitride-based semiconductor; and a Schottky junction layer disposed on the light absorption layer, wherein the ESD prevention layer includes a first nitride layer disposed on the base layer and including a nitride-based semiconductor having an Al composition ratio of 0.9 or more, and a second nitride layer disposed on the first nitride layer and including a nitride-based semiconductor having a lower Al composition ratio than the first nitride layer, the first nitride layer includes at least one pit formed on an upper portion thereof and has a higher defect density than the second nitride layer.

The second nitride layer may fill the at least one pit and include at least one defect concentrated portion extending from the at least one pit.

According to some exemplary embodiments, a method of fabricating a light detection device includes: forming a base layer including a nitride-based semiconductor on a substrate; forming a first nitride layer including a nitride-based semiconductor having an Al composition ratio of 0.9 or more on the base layer, the first nitride layer including at least one pit; forming a second nitride layer including a nitride-based semiconductor having a lower Al composition ratio than the first nitride layer on the first nitride layer; forming a light absorption layer including an Al-containing nitride-based semiconductor on the second nitride layer; and forming a Schottky junction layer on the light absorption layer.

The base layer may be grown at a first temperature, the first nitride layer may be grown at a second temperature, and a difference between the first temperature and the second temperature may be higher than 0° C. and 150° C. or less.

The light absorption layer may include AlGaN having an Al composition ratio of 0.4 or more.

Forming the second nitride layer may include forming a defect concentrated portion extending from the at least one pit.

The first nitride layer may be formed of MN and the second nitride layer may be formed of AlGaN.

The method may further include forming a low current blocking layer disposed between the second nitride layer and the light absorption layer and including a multilayer structure layer.

Hereinafter, exemplary embodiments of the present disclosure will be described in detail with reference to the accompanying drawings. The following embodiments are provided by way of example so as to fully convey the spirit of the present disclosure to those skilled in the art to which the present disclosure pertains. Accordingly, the present disclosure is not limited to the embodiments disclosed herein and can also be implemented in different forms. In the drawings, widths, lengths, thicknesses, and the like of elements can be exaggerated for clarity and descriptive purposes. It will be understood that when an element such as a layer, film, region or substrate is referred to as being “on” another element, it can be directly on the other element or intervening elements may also be present. In contrast, when an element is referred to as being “directly on” another element, there are no intervening elements present. Throughout the specification, like reference numerals denote like elements having the same or similar functions.

It should be understood that compositions, growth methods, growth conditions, thicknesses, and the like of semiconductor layers described below are provided by way of example and the present disclosure is not limited thereto. For example, in a formula represented by AlGaN, a composition ratio of Al to Ga may be modified in various ways by a person having ordinary knowledge in the art (hereinafter, “those skilled in the art”) as needed. In addition, the semiconductor layers described below may be grown by various methods known to those skilled in the art, for example, metal organic chemical vapor deposition (MOCVD), molecular beam epitaxy (MBE), or hydride vapor phase epitaxy (HYPE). In the following exemplary embodiments, semiconductor layers will be described as being grown within the same chamber by MOCVD, and any sources known to those skilled in the art may be used without limitation according to the composition ratio for growth of the semiconductor layers.

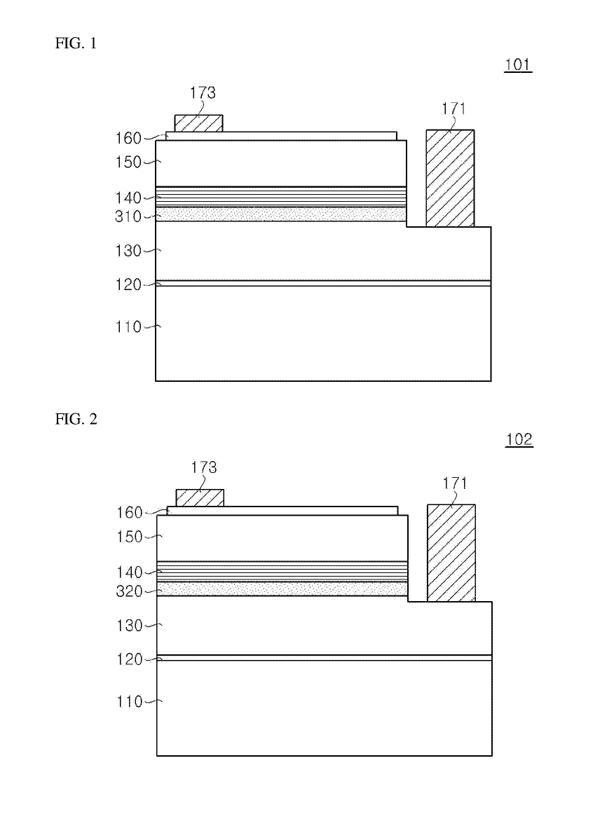

FIG. 1 is a sectional view of a light detection device 101 according to one exemplary embodiment of the present disclosure. The light detection device 101 includes a base layer 130, a light absorption layer 150, a Schottky junction layer 160, and an ESD prevention layer 310. The light detection device 101 may further include a substrate 110, a buffer layer 120, a low current blocking layer 140, a first electrode 171, and a second electrode 173.

The substrate 110 is placed at the bottom of the device and may be selected from any substrates that permit growth of semiconductor layers thereon. For example, the substrate 110 may include a sapphire substrate, a SiC substrate, a ZnO substrate, and a nitride-based substrate such as a GaN substrate or an MN substrate. In this exemplary embodiment, the substrate 110 may be a sapphire substrate. The substrate 110 may be omitted.

The base layer 130 may be disposed on the substrate 110. The base layer 130 may include a nitride-based semiconductor layer, for example, a GaN layer. The base layer 130 may be doped with an n-type dopant, such as Si, or may be undoped. Since the nitride-based semiconductor exhibits n-type characteristics even in an undoped state, doping of the nitride-based semiconductor may be determined as needed. When the base layer 130 is doped with n-type dopants including Si, the doping concentration of Si may be 1×10⁸ or less. The base layer 130 may have a thickness of about 2 μm.

The buffer layer 120 may be interposed between the base layer 130 and the substrate 110. The buffer layer 120 may include a similar material to the material of the base layer 130, for example, a GaN layer. The buffer layer 120 may have a thickness of about 25 nm and may be grown at a lower temperature (for example, 500° C. to 600° C.) than the base layer 130. The buffer layer 120 serves to improve crystallinity of the base layer 130, thereby improving optical and electrical characteristics of the base layer 130. Further, in an exemplary embodiment wherein the substrate 110 is a heterogeneous substrate such as a sapphire substrate, the buffer layer 120 may act as a seed layer for growth of the base layer 130.

Each of the base layer 130 and the buffer layer 120 may be composed of a single layer or multiple layers. The base layer 130 may include GaN layers grown under different process conditions, for example, different growth temperatures, growth pressures and source flow rates. Accordingly, the concentration of the n-type dopant in the base layer 130 may differ depending upon the growth direction. Further, in a structure wherein the base layer 130 includes a ternary nitride semiconductor such as AlGaN and InGaN or a quaternary nitride semiconductor such as AlInGaN, the base layer may be composed of nitride semiconductor layers having different composition ratios. For example, the base layer 130 may include at least one u-GaN layer and at least one n-GaN layer formed on the u-GaN layer. In some exemplary embodiments, each of the u-GaN layer and the n-GaN layer may be provided in plural, and a plurality of u-GaN layers and a plurality of n-GaN layers may include u-GaN layers and n-GaN layers grown under different conditions.

The low current blocking layer 140 may be disposed on the base layer 130. In some exemplary embodiments, the low current blocking layer 140 may be disposed on the ESD prevention layer 310. The low current blocking layer 140 may include a multilayer structure layer.

The multilayer structure layer may include binary to quaternary nitride layers including (Al, In, Ga)N, and may have a structure wherein at least two nitride layers having different composition ratios are repeatedly stacked one above another. In this structure, each of the nitride semiconductor layers may have a thickness of 5 nm to 10 nm. In some exemplary embodiments, the multilayer structure layer may include a structure wherein 3 to 10 pairs of nitride layers having different composition ratios are stacked one above another.

The nitride semiconductor layers stacked in the multilayer structure layer may be determined based on the composition of a nitride layer of the light absorption layer 150. For example, for the light absorption layer 150 including an AlGaN layer, the multilayer structure layer may have a stack structure of AlN/AlGaN layers or AlGaN/AlGaN layers. Further, for the light absorption layer 150 including InGaN, the multilayer structure layer may have a stack structure of InGaN/InGaN layers, GaN/InGaN layers, or AlInGaN/AlInGaN layers, and for the light absorption layer 150 including GaN, the multilayer structure layer may have a stack structure of GaN/InGaN layers, InGaN/InGaN layers or GaN/GaN layers. The stack structure may be formed by stacking 3 to 10 pairs of nitride layers and the low current blocking layer may have a thickness of 10 nm to 100 nm.

Each of the at least two nitride layers may be grown to a thickness of 5 nm to 10 nm so as to have different composition ratios through adjustment of flow rates of source gases. Alternatively, the at least two nitride layers having different composition ratios may be formed by stacking nitride layers under different pressures in a growth chamber while maintaining other conditions including the flow rates of source gases.

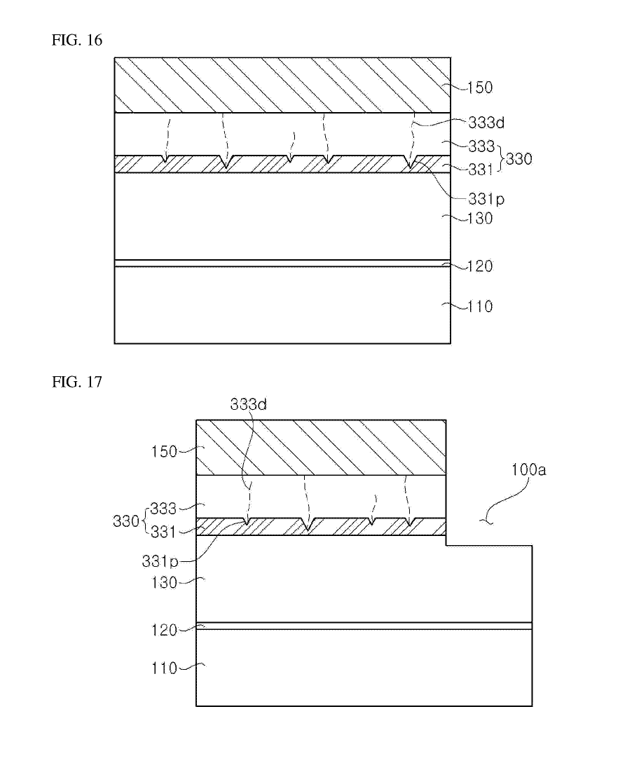

In the low current blocking layer 140, the energy band gap of an interface between layers of the multilayer structure layer may be greater than that of other portions. FIG. 10a and FIG. 10b shows data obtained using an atom probe and TEM images for measurement of the composition ratio. The light absorption layer is formed to a depth from 0 to 90 nm and the low current blocking layer 140 is formed from a depth deeper than 90 nm, that is, at a lower end of the light absorption layer. From FIG. 10a and FIG. 10b, it can be seen that the interface between the layers of the multilayer structure layer has a higher Al composition ratio. As such, in the structure wherein a thin layer having a high Al composition ratio is present at the interface between the layers of the multilayer structure layer, interface resistance between the light absorption layer 150 and the base layer 130 is effectively lowered by the tunneling effect, thereby reducing loss of photoelectrons while improving measurement sensitivity.

The stack structure of nitride layers having different composition ratios may be provided by growing the nitride layers at different pressures. For example, in order to form a multilayer structure layer having a structure wherein AlₓGa₍₁₋ₓ₎N layers and Al_{y}Ga_{(1-y)}N layers are repeatedly stacked one above another, the AlₓGa₍₁₋ₓ₎N layers are grown at a pressure of about 100 Torr and the Al_{y}Ga_{(1-y)}N layer are grown at a pressure of about 400 Torr. Under the same growth conditions excluding the pressure, the AlₓGa₍₁₋ₓ₎N layers grown at a lower pressure can have a higher Al composition ratio than the Al_{y}Ga_{(1-y)}N layers grown at a higher pressure.

For example, in order to form the multilayer structure layer including the structure wherein AlₓGa₍₁₋ₓ₎N layers and Al_{y}Ga_{(1-y)}N layers are repeatedly stacked one above another, the AlₓGa₍₁₋ₓ₎N layers are grown at a pressure of about 100 Torr and the Al_{y}Ga_{(1-y)}N layers are grown at a pressure of about 400 Torr. Under the same growth conditions excluding pressure, the AlₓGa₍₁₋ₓ₎N layers grown at a lower pressure can have a higher Al composition ratio than the Al_{y}Ga_{(1-y)}N layers grown at a higher pressure. As such, the low current blocking layer 140 including the multilayer structure layer formed through growth at different pressures can improve crystallinity of the light absorption layer 150 formed on the low current blocking layer 140 by preventing generation and propagation of dislocations during growth. In addition, since the nitride layers having different composition ratios are repeatedly stacked one above another through growth at different pressures, the occurrence of cracking in the light absorption layer 150 can be prevented by relieving stress caused by a difference in lattice parameter. Furthermore, the nitride layers are grown by changing pressure while maintaining the flow rates of source gases, thereby enabling easy formation of the low current blocking layer 140.

In this way, the nitride layers grown at different pressures may have different growth rates due to a difference in growth pressure. As the nitride layers have different growth rates, the low current blocking layer can block propagation of dislocations or change a propagation path of the dislocations during growth, thereby reducing dislocation density of other semiconductor layers grown in subsequent processes. Furthermore, since the stack structure wherein layers repeatedly stacked one above another have different composition ratios can relieve stress caused by a difference in lattice parameter, it is possible to secure good crystallinity of other semiconductor layers grown in the subsequent processes and to prevent occurrence of damage such as cracks. Particularly, in a structure wherein an AlGaN layer having an Al composition ratio of 15% or more is grown on the low current blocking layer 140, the occurrence of cracks in the AlGaN layer can be effectively prevented, thereby solving the problem of crack occurrence upon formation of the AlGaN layer on an MN layer or a GaN layer in the related art. According to this exemplary embodiment, the low current blocking layer 140 including the multilayer structure layer is formed under the light absorption layer 150, so that the light absorption layer 150 can have good crystallinity and can be prevented from suffering from cracking. As the light absorption layer 150 has good crystallinity, the light detection device 101 can have improved quantum efficiency.

The low current blocking layer 140 may have a higher defect density than the light absorption layer 150. As the low current blocking layer 140 has a higher defect density than the light absorption layer 150, the light absorption layer 150 can prevent a flow of electrons generated through reaction with visible light. A low current blocking function of the low current blocking layer 140 will be described in detail below.

The ESD prevention layer 310 is disposed on the base layer 130. The ESD prevention layer 310 may include a nitride-based semiconductor such as (Al, In, Ga)N, and may include, for example, GaN. Further, the ESD prevention layer 310 may have a lower average n-type dopant concentration than the base layer 130. Furthermore, the ESD prevention layer 310 may include an undoped nitride-based semiconductor, for example, u-GaN, and may be formed of u-GaN. The ESD prevention layer 310 may be formed substantially under similar conditions to the growth conditions of the base layer 130. The ESD prevention layer 310 may have a smaller thickness than the low current blocking layer 140. For example, the ESD prevention layer 310 may include one or more undoped nitride-based semiconductor layers, and a total thickness of the undoped nitride-based semiconductor layers may range from about 200 nm to 400 nm, specifically from about 300 nm to 400 nm. However, it should be understood that the present disclosure is not limited thereto.

Since the ESD prevention layer 310 has a relatively low average n-type dopant and includes the undoped nitride-based semiconductor, the light detection device 101 can have improved electrostatic discharge resistance. Particularly, with the structure wherein the ESD prevention layer 310 including the undoped nitride-based semiconductors is interposed between the base layer 130 and the light absorption layer 150, the light detection device 101 can have improved internal capacitance, thereby improving electrostatic discharge resistance. As a result, the light detection device 101 according to this exemplary embodiment has the Schottky junction while exhibiting several times or more electrostatic discharge resistance than a typical light detection device.

The light absorption layer 150 is disposed on the low current blocking layer 140.

The light absorption layer 150 may include a nitride semiconductor layer, for example, at least one layer of a GaN layer, an InGaN layer, an AlInGaN layer and an AlGaN layer. Since the energy band-gap of the nitride semiconductor layer is determined based on the kind of group III element therein, nitride semiconductor materials of the light absorption layer 150 can be determined by taking into account the wavelength of light to be detected by the light detection device 101. For example, in the light detection device 101 configured to detect UV light in the UVA band, the light absorption layer 150 may include a GaN layer or an InGaN layer; in the light detection device 101 configured to detect UV light in the UVB band, the light absorption layer 150 may include an AlGaN layer having an Al composition ratio of 28% or less; and in the light detection device 101 configured to detect UV light in the UVC band, the light absorption layer 150 may include an AlGaN layer having an Al composition ratio of 28% to 50%. However, it should be understood that the present disclosure is not limited thereto.

The light absorption layer 150 may have a thickness of about 0.1 μm to 0.5 μm, and may have a thickness of 0.1 μm or more in order to improve light detection efficiency. In a typical light detection device, since the light absorption layer 150 is formed on the MN layer or the GaN layer, there is a problem that cracks can be easily generated in the light absorption layer 150 that includes an AlGaN layer having an Al composition ratio of 15% and has a thickness of 0.1 μm or more. Thus, the light absorption layer 150 of the typical light detection device has a thin thickness of 0.1 μm or less, thereby causing low yield and low light detection efficiency. Conversely, according to the exemplary embodiments, since the light absorption layer 150 is formed on the low current blocking layer 140 including the multilayer structure layer, the light absorption layer 150 can be prevented from occurrence of cracking and thus can be formed to a thickness of 0.1 μm or more. Accordingly, the light detection device 101 according to the exemplary embodiments has high light detection efficiency.

The Schottky junction layer 160 is disposed on the light absorption layer 150. The Schottky junction layer 160 and the light absorption layer 150 can form Schottky junction with each other, and the Schottky junction layer 160 may include at least one of ITO, Ni, Co, Pt, W, Ti, Pd, Ru, Cr, and Au. The thickness of the Schottky junction layer 160 may be regulated by taking light transmission and Schottky characteristics into account, and may be, for example, 10 nm or less.

The light detection device 101 may further include a cap layer (not shown) interposed between the Schottky junction layer 160 and the light absorption layer 150. The cap layer may be a p-type nitride semiconductor layer doped with a p-type dopant such as Mg. The cap layer may have a thickness of 100 nm or less, preferably 5 nm or less. The cap layer can improve the Schottky characteristics of the device.

Referring to FIG. 1 again, the light detection device 101 may include an exposed region of the base layer 130, which is formed by partially removing the light absorption layer 150 and the low current blocking layer 140 to expose a surface of the base layer 130. The first electrode 171 may be disposed on the exposed region of the base layer 130 and the second electrode 173 may be disposed on the Schottky junction layer 160.

The first electrode 171 may form ohmic contact with the base layer 130 and may be composed of multiple layers including a metal. For example, the first electrode 171 may have a stack structure of Cr/Ni/Au layers. The second electrode 173 may include a metal and may be composed of multiple layers. For example, the second electrode 173 may have a stack structure of Ni layer/Au layer. However, it should be understood that the present disclosure is not limited thereto. Namely, the second electrode 173 and the first electrode 171 may have any structure so long as the second electrode 173 and the first electrode 171 are electrically connected to the Schottky junction layer 160 and the base layer 130, respectively.

On the other hand, the light detection device 101 according to this exemplary embodiment may include nitride-based semiconductors having various composition ratios depending upon wavelengths of light to be detected. For example, the light detection device 101 may be a device configured to detect UV light in the UVB band. To this end, the light absorption layer 150 may include at least one of AlGaN and AlInGaN, and may be formed of AlGaN having an Al composition ratio of, for example, about 30% or less. Furthermore, the low current blocking layer 140 may have a super lattice structure including 5 pairs of AlₓGa₍₁₋ₓ₎N layers and Al_{y}Ga_{(1-y)}N layer (x≠y) repeatedly stacked one above another. However, it should be understood that the present disclosure is not limited thereto.

The following detailed description will be given of functions of the low current blocking layer 140 according to the operating principle of the light detection device 101.

With an external power source connected to the second electrode 173 and the first electrode 171 of the light detection device 101 and no voltage or reverse voltage applied thereto, the light detection device 101 is prepared. When the prepared light detection device 101 is illuminated, the light absorption layer 150 absorbs the light reaching the light detection device 101. In the structure wherein the Schottky junction layer 160 is formed on the light absorption layer 150, an electron-hole separation region, that is, a depletion region, is formed between interfaces. When electric current is generated by electrons generated by the light, the light detection device measures the electric current, thereby performing light detection.

For example, when the light detection device 101 is a UV light detection device, an ideal UV light detection device has an infinite UV-to-visible light rejection ratio. However, in a typical UV light detection device, electric current is generated through reaction of the light absorption layer with visible light due to inherent defects of the light absorption layer. Thus, the typical light detection device has a UV-to-visible rejection ratio of 10³ or less, causing failure in detection of light.

Conversely, in the light detection device 101 according to the exemplary embodiment, electrons generated in the light absorption layer 150 by visible light are captured by the low current blocking layer 140, thereby preventing operation of the light detection device by visible light as much as possible. As described above, the low current blocking layer 140 has a higher defect density than the light absorption layer 150. In the light detection device according to the exemplary embodiment, the amount of electrons generated by visible light is much smaller than the amount of electrons generated by UV light, whereby movement of electrons can be efficiently blocked only by defects present in the low current blocking layer 140. That is, the low current blocking layer 140 has a higher defect density than the light absorption layer 150, thereby preventing movement of electrons generated by visible light. On the other hand, the amount of electrons generated by irradiation of the light absorption layer 150 with UV light is much greater than the amount of electrons generated by visible light, and thus allows flow of electric current without being captured by the low current blocking layer 140. Therefore, the light detection device 101 according to the exemplary embodiment exhibits very low reactivity with visible light and thus can have a higher UV-to-visible rejection ratio than a typical UV light detection device. Particularly, the light detection device 101 according to the exemplary embodiment has a UV-to-visible rejection ratio of 10⁴ or more. Thus, according to the exemplary embodiments, the light detection device has high detection efficiency and high reliability.

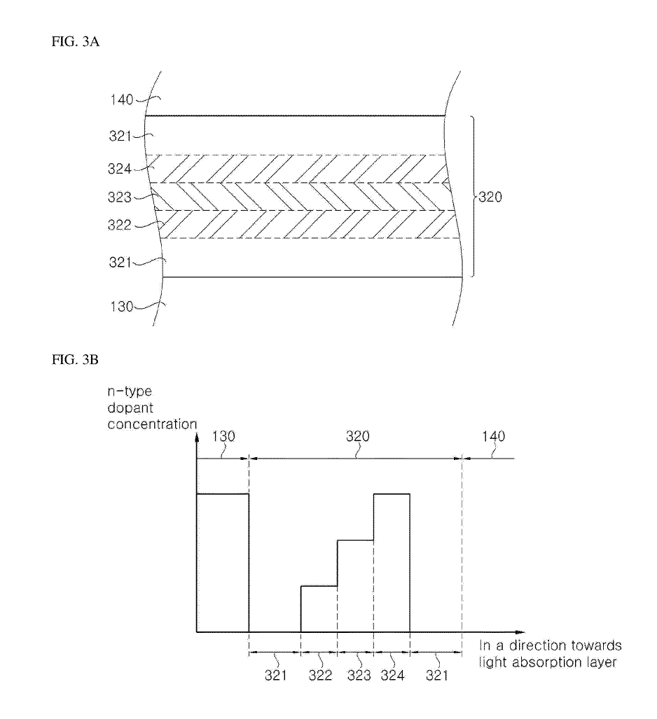

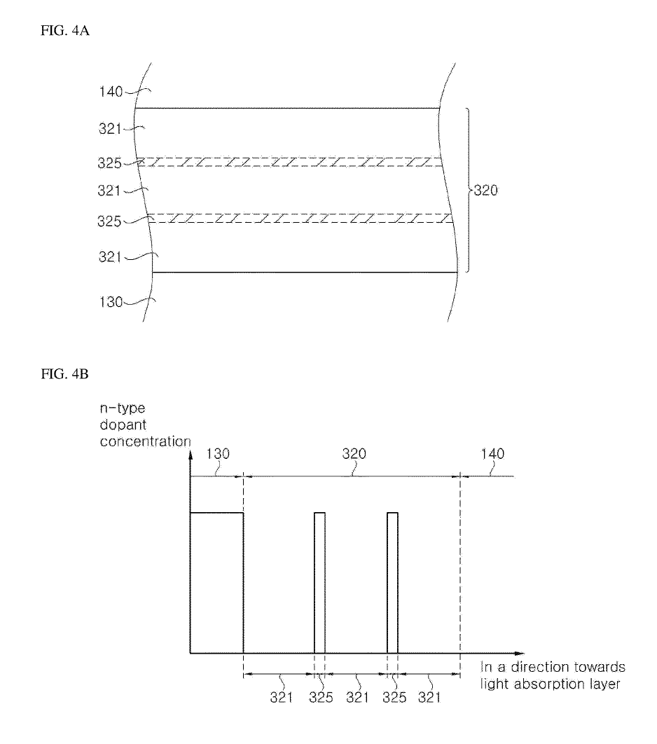

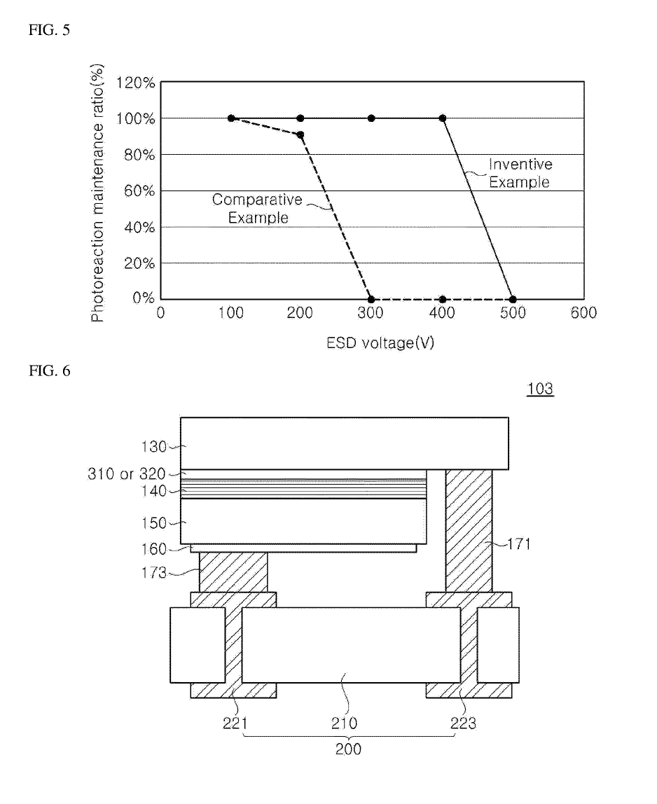

FIG. 2 is a sectional view of a light detection device according to another exemplary embodiment of the present disclosure, and FIG. 3a to FIG. 4b are enlarged views and graphs depicting an ESD prevention layer of each of light detection devices according to other exemplary embodiments of the present disclosure. FIG. 3a and FIG. 4a are enlarged views of an ESD prevention layer 320 of each of the light detection devices according to the exemplary embodiments and FIG. 3b and FIG. 4b are graphs depicting variation of concentration of an n-type dopant in a direction of a light absorption layer 150 of each of the light detection devices according to the exemplary embodiments.

Unlike the light detection device 101 of FIG. 1, a light detection device 102 of FIG. 2 includes an ESD prevention layer 320 which further includes doped regions. The following description will be mainly given of different features of the light detection device according to this exemplary embodiment and a detailed description of the same components will be omitted.

The light detection device 102 includes a base layer 130, a low current blocking layer 140, a light absorption layer 150, a Schottky junction layer 160, and an ESD prevention layer 320. The light detection device 102 may further include a substrate 110, a buffer layer 120, a first electrode 171, and a second electrode 173. Although the ESD prevention layer 320 is generally similar to the ESD prevention layer 310 of FIG. 1, the ESD prevention layer 320 may further include a doped region including an n-type dopant. The n-type dopant may include a dopant known in the art, such as Si, Ge, Sn, or the like.

First, referring to FIG. 3a and FIG. 3b, an ESD prevention layer 320 according to one exemplary embodiment includes at least one doped region (at least one of 322, 323 and 324). The doped region 322, 323 or 324 may be formed in plural. For example, the doped regions 322, 323, 324 may include a first doped region 322, a second doped region 323, and a third doped region 324. The second doped region 323 may be disposed on the first doped region 322 and the third doped region 324 may be disposed on the second doped region 323. The doped regions 322, 323, 324 may adjoin one another or may be separated from each other.

In addition, the doped regions 322, 323, 324 may have different doping concentrations. Further, doping profiles of the doped regions 322, 323, 324 may increase or decrease in a certain direction. For example, as shown in FIG. 3b, the second doped region 323 may have a higher doping concentration than the first doped region 322 and the third doped region 324 may have a higher doping concentration than the second doped region 323. Accordingly, the doping concentration of the first to third doped regions 322, 323, 324 may gradually increase towards the light absorption layer 150. Here, the increasing rate of the doping concentration may be constant or irregular. Furthermore, one doped region 322, 323 or 324 may have an increasing or decreasing doping profile of the n-type dopant, or a modulation doped profile thereof. Although the base layer 130 includes the n-type dopant in this exemplary embodiment, it should be understood that the present disclosure is not limited thereto and the base layer 130 may be undoped. Further, an average doping concentration of each of the base layer 130 and the ESD prevention layer 320 may be adjusted in various ways.

Photoelectrons generated in the light absorption layer 150 pass through the third doped region 324 and then laterally move through the first doped region 322 to enter the first electrode 171. Here, the third doped region 324 is formed in a high concentration to allow the photoelectrons to be easily moved into a current spreading layer and to horizontally move through the first doped region 322. A high doping concentration provides high diffusivity, thereby enabling easy transmission of the photoelectrons through the first doped region 322. On the contrary, since a high concentration of the n-type dopant (for example, Si) can act as resistance with respect to lateral movement of the photoelectrons, a low concentration layer is formed near a high concentration layer in order to improve efficiency in injection and lateral movement of the photoelectrons.

Referring to FIG. 4a and FIG. 4b, an ESD prevention layer 320 according to some exemplary embodiments includes doped regions, which may include at least one n-type dopant shock layer 325.

The ESD prevention layer 320 may include an n-type dopant shock layer 325 formed by doping an n-type dopant into a relatively thin region. The n-type dopant shock layer 325 may be formed to a smaller thickness than the first to third doped regions 322, 323, 324 described with reference to FIG. 3a and FIG. 3b, or may be formed to a thickness which can be obtained by delta doping. The n-type dopant shock layer 325 may be formed in plural, and a plurality of n-type dopant shock layers 325 may be arranged at regular intervals or at irregular intervals in the ESD prevention layer 320. Further, the n-type dopant shock layers 325 may be disposed in the ESD prevention layer such that a distance between the n-type dopant shock layers gradually increases or decreases towards the light absorption layer 150.

As shown in FIG. 3a to FIG. 4b, since the doped regions 322, 323, 324, 325 are disposed inside the ESD prevention layer 320, undoped regions (undoped nitride-based semiconductors) 321 may be disposed on upper and lower sides of the doped regions 322, 323, 324, 325. Thus, in the ESD prevention layer 320, the undoped regions 321 may adjoin at least one of the low current blocking layer 140 and the base layer 130.

With the structure wherein the undoped region is further added between the doped regions, the light detection device reduces resistance with respect to movement of photoelectrons into the first electrode 171 upon operation while generating a broad depletion region upon application of ESD.

With the structure wherein the ESD prevention layer 320 includes the n-type dopant doped regions, expansion of the depletion region is suppressed by the doped regions. Accordingly, electrostatic discharge resistance of the light detection device 102 can be further improved. Further, resistance in the ESD prevention layer 320 is reduced by the doped regions of the ESD prevention layer 320, electric current can smoothly flow through the light detection device upon operation, thereby improving light detection efficiency of the light detection device.

The light detection device 102 according to the above exemplary embodiments includes the low current blocking layer 140 and the ESD prevention layer 320, thereby preventing damage due to static electricity. With this structure, the light detection device 102 can prevent deterioration in reliability due to use over time, thereby preventing increase in UV-to-visible rejection ratio due to use of the light detection device 102 in practical application.

### Experimental Example 1

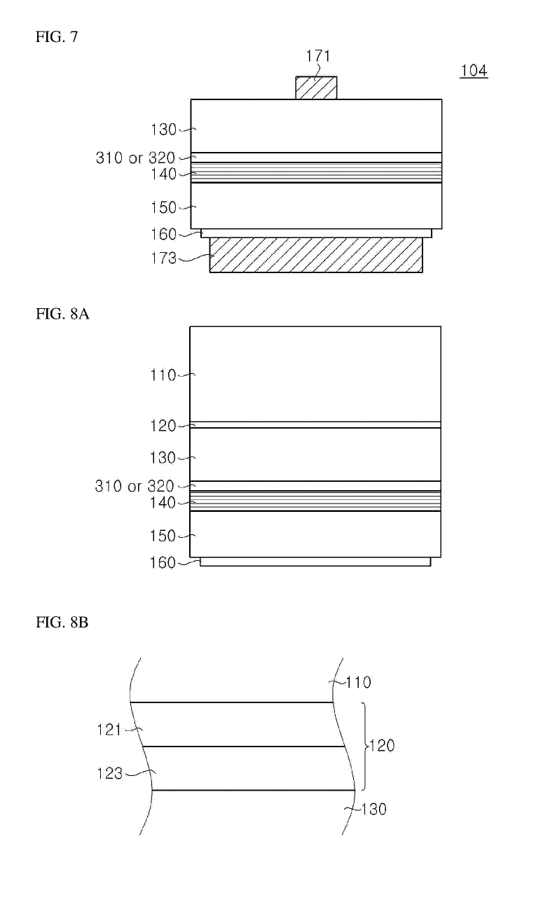

FIG. 5 is a graph comparing characteristics of light detection devices prepared in Experimental Example.

In this experimental example, a light detection device prepared in an inventive example is generally similar to the light detection device of FIG. 1 and a light detection device prepared in a comparative example does not include the ESD prevention layer 310 of the light detection device of FIG. 1. In this experiment, ESD voltages of 100V, 200V, 300V, 400V and 500V were sequentially applied to measure photoreaction ratios of the light detection devices of the inventive example and the comparative example.

In FIG. 5, it can be seen that the light detection device of the inventive example maintained a photoreaction ratio of substantially 100% even upon application of an ESD voltage of 400V. Conversely, the light detection device of the comparative example had a reduced photoreaction ratio upon application of an ESD voltage of 200V and lost the light detection function due to failure upon application of an ESD voltage of 300V. As such, it can be seen from this experimental example that the light detection device including the ESD prevention layer did not suffer from failure even by application of ESD voltage two times or higher the ESD voltage applied to the light detection device not including the ESD prevention layer.

### Experimental Example 2

This experiment was performed in order to determine an effective thickness of the ESD prevention layer. The light detection device used in this experiment includes a substrate, an about 3 μm thick n-type GaN base layer, a u-GaN ESD prevention layer, a light absorption layer, and a Ni Schottky contact layer. Further, a mesa exposing the n-type GaN base layer has a depth of about 0.6 μm and a first electrode and a second electrode were formed on the Ni Schottky contact layer and the n-type GaN base layer, respectively.

Table 1 shows measurement results of photocurrent and ESD yield depending upon thickness of the u-GaN ESD layer. Here, the ESD yield refers to percentage of chips not suffering from short circuit upon application of 400V to 100 chips classified according to ranks. The photocurrent refers to electric current generated upon application of 1V while irradiating with UVB light using an LED.

TABLE 1

| n-GaN thickness (nm) | Photocurrent (nA) | ESD yield (%) |
|---|---|---|
| — | 43.74 | 53.4 |
| 100 | 56.97 | 62.1 |
| 200 | 52.15 | 63.7 |
| 300 | 78.18 | 88.5 |
| 400 | 71.04 | 90.5 |
| 500 | 60.5 | 90.6 |

As shown in Table 1, it can be seen that ESD yield was significantly increased when the u-GaN ESD prevention layer had a thickness of 300 nm or more. It is analyzed that this result was caused by lateral spreading of photoelectrons by the ESD prevention layer since the n-type dopant reduced mobility of electrons. However, as the thickness of the ESD prevention layer exceeded 300 nm, the photocurrent was decreased. It is analyzed that this result was caused by the u-GaN layer acting as a resistor in view of vertical movement of electrons. It can be seen that the ESD yield continued to rapidly increase until the thickness of the ESD prevention layer reached 400 nm and then the increase rate was lowered when the thickness of the ESD prevention layer exceeded 400 nm. In summary, it can be seen that, when the u-GaN layer in the ESD prevention layer has a thickness of about 200 to 400 nm, the light detection device exhibits excellent characteristics in terms of ESD and photocurrent, and that when the ESD prevention layer had a thickness of about 300 nm, the light detection device has optimal effects. It should be understood that the present disclosure is not limited to this experimental example.

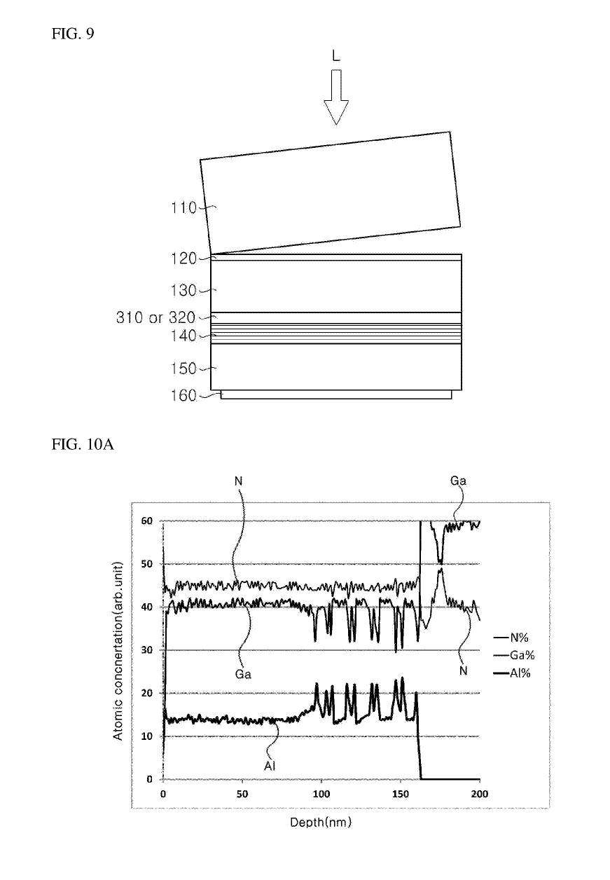

FIG. 6 is a sectional view of a light detection device according to yet another exemplary embodiment of the present disclosure. A light detection device 103 according to this exemplary embodiment is generally similar to the light detection device 101 shown in FIG. 1 except that the light detection device 103 may be flip-bonded to a secondary substrate 200. The following description will be mainly given of different features of the light detection device 103 and a detailed description of the same components will be omitted.

Referring to FIG. 6, the light detection device 103 includes a base layer 130, a low current blocking layer 140, an ESD prevention layer 310 or 320, a light absorption layer 150, and a Schottky junction layer 160. The light detection device 103 may further include a first electrode 171 and a second electrode 173 and may be flip-bonded to the secondary substrate 200 so as to be provided as a light detection device package. The secondary substrate 200 may include a base 210, a first lead electrode 221 and a second lead electrode 223, and the first and second electrodes 171, 173 of the light detection device 103 may be electrically connected to the first and second lead electrodes 221, 223 of the secondary substrate 200, respectively.

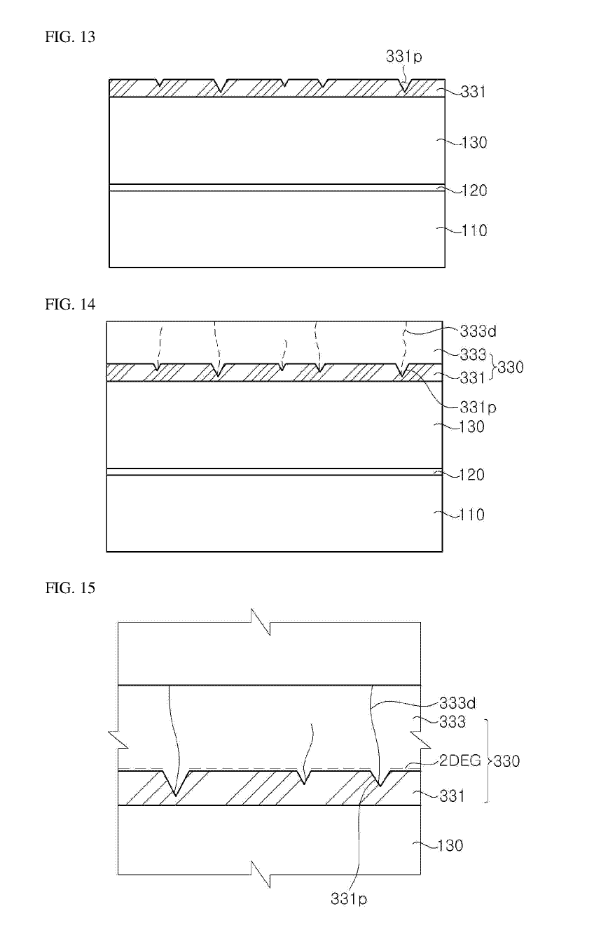

The light detection device 103 according to this exemplary embodiment is different from the light detection device 101 of FIG. 1 in that the substrate 110 is removed from the base layer 130. The substrate 110 may be removed from the base layer 130 by at least one of laser lift-off, chemical lift-off, thermal lift-off and stress lift-off. This will be described below in detail with reference to FIG. 8 and FIG. 9. Alternatively, the substrate 110 may remain on the base layer 130 instead of being removed therefrom.

Upon operation of the light detection device 103 according to this exemplary embodiment, light generally enters the light detection device through an upper surface of the light detection device 103, that is, an upper surface of the base layer 130. In order to allow efficient operation of the light detection device 103, it is desirable that the light reach the light absorption layer 150 after passing through the base layer 130. Accordingly, the base layer 130 may be formed of a nitride semiconductor containing Al in a predetermined concentration. For a UV light detection device, the base layer 130 may have a greater energy band gap than the light absorption layer 150. For example, when the light detection device 103 according to this exemplary embodiment is a UV light detection device configured to detect UV light in the UVB band, the base layer 130 may include AlGaN having an Al composition ratio of about 28% or more. With this structure, the light detection device 103 can minimize absorption of incident light into the base layer 130 before the light reaches the light absorption layer 150. It should be understood that the present disclosure is not limited thereto and that components and the composition ratio of the base layer 130 may be set in various ways depending upon the wavelengths of light to be detected by the light detection device 103.

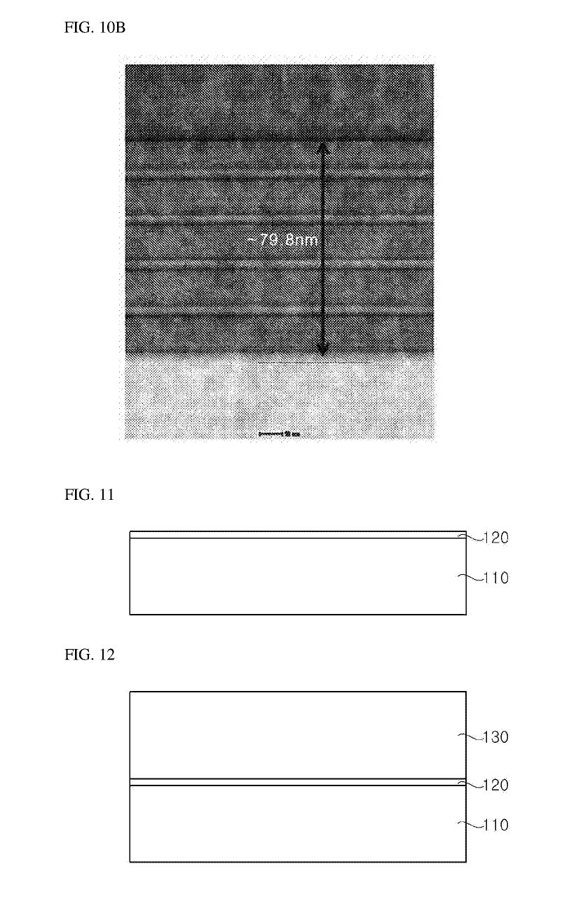

FIG. 7 is a sectional view of a light detection device according to yet another exemplary embodiment of the present disclosure. A light detection device 104 according to this exemplary embodiment is generally similar to the light detection device 101 shown in FIG. 1 except that the light detection device 104 is a vertical type. The following description will be mainly given of different features of the light detection device 104 and a detailed description of the same components will be omitted.

Referring to FIG. 7, the light detection device 104 includes a base layer 130, a low current blocking layer 140, an ESD prevention layer 310 or 320, a light absorption layer 150, and a Schottky junction layer 160. The light detection device 104 may further include a first electrode 171 and a second electrode 173.

The light detection device 104 according to this exemplary embodiment is different from the light detection device 101 of FIG. 1 in that the substrate 110 is removed from the base layer 130 and the first electrode 171 is disposed on an exposed upper surface of the base layer 130 from which the substrate 110 is separated. That is, the second electrode 173 and the first electrode 171 may be vertically disposed. The substrate 110 may be removed from the base layer 130 by at least one of laser lift-off, chemical lift-off, thermal lift-off and stress lift-off. This will be described below in detail with reference to FIG. 8 and FIG. 9.

As in the light detection device 103 of FIG. 6, upon operation of the light detection device 104 according to this exemplary embodiment, light generally enters the light detection device through an upper surface of the light detection device 104, that is, an upper surface of the base layer 130. Accordingly, components and the composition ratio of the base layer 130 may be set in various ways depending upon the wavelengths of light to be detected by the light detection device 104.

Next, referring to FIG. 8a to FIG. 9, the method of separating the substrate 110 through laser lift-off in fabrication of the light detection devices according to the exemplary embodiment shown in FIG. 6 and FIG. 7 will be described in more detail.

First, FIG. 8a shows the light detection device before separation of the substrate 110. The light detection device includes the Schottky junction layer 160, the light absorption layer 150 disposed on the Schottky junction layer 160, the low current blocking layer 140 disposed on the light absorption layer 150, the base layer 130 disposed on the low current blocking layer 140, the buffer layer 120 disposed on the base layer 130, and the substrate 110.

As shown in FIG. 8b, the buffer layer 120 may include a seed buffer layer 121 and a compensation layer 123. The seed buffer layer 121 may be disposed under a lower surface of the substrate 110 and may include a nitride semiconductor having an Al composition ratio of 1% or less. For example, the seed buffer layer 121 may be formed of GaN. The compensation layer 123 may serve to relieve stress caused by a difference in lattice parameter between the seed buffer layer 121 and the base layer 130. Accordingly, the compensation layer 123 may include a nitride semiconductor having an Al composition ratio that is higher than that of the seed buffer layer 121 and is lower than that of the base layer 130. In addition, the compensation layer 123 may include multiple layers or a composition gradient layer, the Al composition ratio of which gradually increases in a direction from the seed buffer layer 121 towards the base layer 130.

Upon separation of the substrate using laser lift-off, the substrate 110 is irradiated with a laser beam from an upper surface thereof in a downward direction. To this end, a KrF excimer laser is generally used. On the other hand, since the KrF excimer laser has a wavelength of 248 nm, some laser beams pass through the buffer layer 120 instead of being absorbed therein when the buffer layer 120 disposed between the substrate 110 and the base layer 130 includes Al. This phenomenon can become severer when the buffer layer 120 has a higher Al composition ratio. According to this exemplary embodiment, the buffer layer 120 includes the seed buffer layer 121 formed of a material including substantially no Al, for example, GaN, laser beams can be absorbed into the seed buffer layer 121 upon application of laser lift-off. Accordingly, the substrate 110 can be easily separated from the base layer using the KrF excimer laser, thereby facilitating the process of fabricating the light detection device according to the exemplary embodiments.

On the other hand, as described above, in the light detection devices according to the exemplary embodiments shown in FIG. 6 and FIG. 7, the base layer 130 may have a predetermined Al composition ratio determined depending upon the wavelengths of light to be detected by the light detection device. In the structure wherein the seed buffer layer 121 is formed of GaN, stress is generated due to a difference in lattice parameter between the seed buffer layer 121 and the base layer 130 including Al, and when the stress becomes severe, the concentration of defects such as dislocations increases and can cause cracking. According to this exemplary embodiment, the compensation layer 123 may be interposed between the seed buffer layer 121 and the base layer 130 to prevent increase in concentration of defects in the base layer 130 by relieving stress due to a difference in lattice parameter.

Next, referring to FIG. 9, the substrate 110 may be separated from the base layer 130 by irradiating the upper surface of the substrate 110 with a laser beam L. Here, the substrate 110 may be separated from the buffer layer 120, particularly, from the seed buffer layer 121. After separation of the substrate 110, the remaining buffer layer 120 may be removed through dry etching, wet etching, or a cleaning process known in the art.

The aforementioned method of separating the substrate 110 may be applied to fabrication of the light detection device of FIG. 6 and FIG. 7. According to this exemplary embodiment, the substrate 110 can be separated from the base layer by easily applying laser lift-off while preventing increase in concentration of defects in the base layer 130 due to the seed buffer layer 121 for application of laser lift-off.

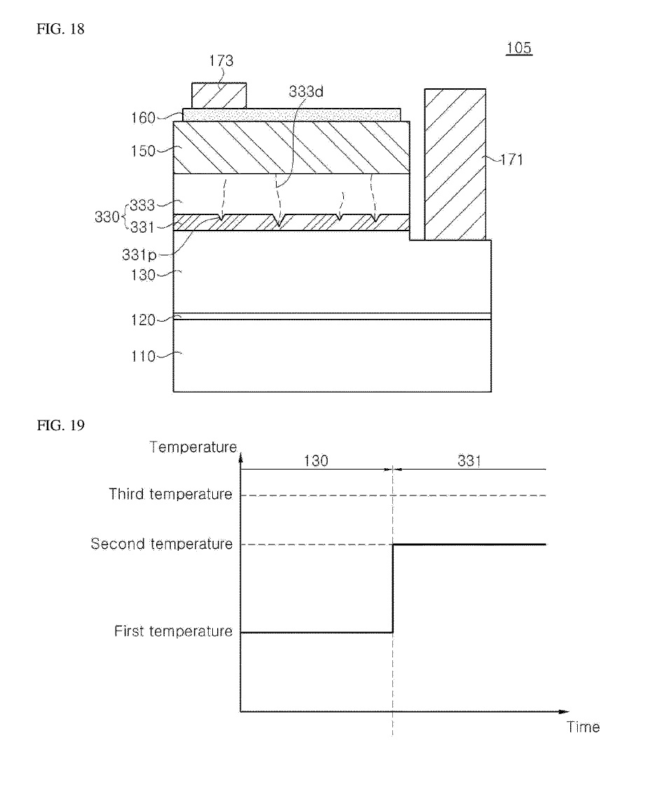

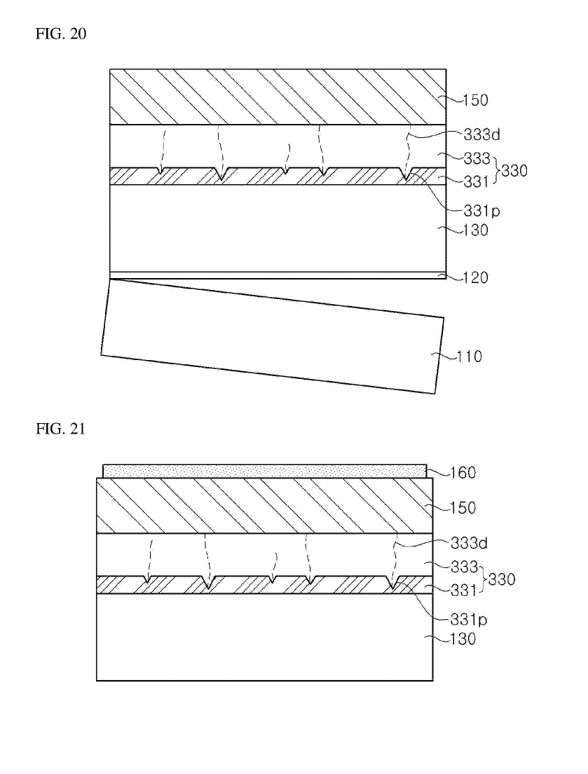

FIG. 11 to FIG. 18 are sectional views and enlarged sectional views of a light detection device according to yet another exemplary embodiment of the present disclosure and a method of fabricating the same, and FIG. 19 is a graph depicting a growth method of a second nitride layer of the light detection device according to the exemplary embodiment of the present disclosure.

Referring to FIG. 11, a substrate 110 is prepared. In addition, a buffer layer 120 may be further formed on the substrate 110.

The substrate 110 may be selected from any substrate that allows growth of nitride-based semiconductor layers thereon. For example, the substrate 110 may include a heterogeneous substrate, such as a sapphire substrate, a SiC substrate, a ZnO substrate, and a Si substrate, or a nitride substrate, that is, a homogeneous substrate, such as a GaN substrate and an MN substrate. For example, in this exemplary embodiment, the substrate 110 may be a sapphire substrate.

The buffer layer 120 may include a nitride semiconductor and may be grown by MOCVD or the like. For example, the buffer layer 120 may be grown by supplying Ga sources and N sources to a growth chamber at a temperature of about 550° C. and a pressure of 100 Torr. Accordingly, the buffer layer 120 may include a GaN layer grown at low temperature. The buffer layer 120 may be grown to a thickness of about 25 nm and can act as a seed layer of semiconductor layers, which will be grown by subsequent processes, as the buffer layer 120 is grown to a thin thickness at low temperature. Further, the buffer layer 120 can improve crystallinity, and optical and electrical characteristics of the semiconductor layers, which will be grown by the subsequent processes. In some exemplary embodiments, the buffer layer 120 may be omitted.

Next, referring to FIG. 12, a base layer 130 is formed on the buffer layer 120.

The base layer 130 may be grown by, for example, MOCVD and may include a nitride-based semiconductor. For example, the base layer 130 may be grown by supplying Ga sources and N sources to the growth chamber at a temperature of about 1050° C. to 1300° C. and a pressure of about 100 Torr to 500 Torr, and thus may include a GaN layer grown at high temperature. Further, the base layer 130 may include an n-type doped GaN layer by further adding a Si source into the growth chamber upon growth thereof, or may include an undoped GaN layer. The base layer 130 may be composed of a single layer or multiple layers. In a structure wherein the base layer 130 is composed of multiple layers, the base layer may include a plurality of u-GaN layers and/or n-GaN layers, which are grown under different conditions. For example, the base layer 130 may include a u-GaN layer grown on the buffer layer 120 and at least one n-GaN layer grown on the u-GaN layer. By forming the u-GaN layer having relatively good crystallinity on the buffer layer 120, it is possible to improve crystallinity of other semiconductor layers grown by subsequent processes. The base layer 130 may be grown to a relatively thick thickness, for example, about 2 μm to 3 μm, without being limited thereto.

The base layer 130 is not limited thereto and may include a nitride-based semiconductor containing Al. The base layer 130 may include at least one AlGaN layer, the Al composition ratio of which may be adjusted in a light incidence direction of the light detection device. For example, when light to be detected by the light detection device is directed from a lower side thereof to an upper side thereof, the base layer 130 may include the nitride-based semiconductor containing Al in order to reduce the ratio of UV light absorbed into the base layer 130.

Next, referring to FIG. 13, a first nitride layer 331 is formed on the base layer 130.

The first nitride layer 331 may be grown on the base layer 130 by, for example, MOCVD and include a nitride-based semiconductor such as (Al, Ga, In)N. Particularly, the first nitride layer 331 may include a nitride-based semiconductor having an Al composition ratio of 0.9 or more and represented by, for example, AlₓGa₍₁₋ₓ₎N (0.9≤x≤1), and may be formed of AlN. As the first nitride layer 331 formed of the nitride-based semiconductor having a high Al composition ratio of 0.9 or more is grown on the base layer 130, it is possible to prevent generation of cracks in a light absorption layer 150 grown in a subsequent process even in the case where the light absorption layer 150 includes a nitride-based semiconductor having a relatively high Al composition ratio (for example, an Al composition ratio of 0.28 or more).

Specifically, in order to realize a light detection device configured to detect UV light having relatively short wavelengths, for example, in the UVC band, the light absorption layer 150 formed of a nitride semiconductor having a relatively large energy band gap is required. Thus, the light absorption layer 150 is required to include a nitride-based semiconductor having a high Al composition ratio, and a probability of crack generation increases with increasing thickness of the nitride-based semiconductor having a high Al composition ratio. According to this exemplary embodiment, the first nitride layer 331 having a high Al composition ratio is formed between the base layer 130 and the light absorption layer 150, thereby preventing generation of cracks in the light absorption layer 150.

Since the first nitride layer 331 is grown on the base layer 130 having a relatively low Al composition ratio or not including Al and has an Al composition ratio of 0.9 or more, cracks can be generated with increasing thickness of the first nitride layer. Accordingly, it is desirable that the first nitride layer 331 be grown to a predetermined thickness or less, and, for example, the first nitride layer 331 may be grown to a thickness of 50 nm or less, specifically 20 nm or less. However, it should be understood that the present disclosure is not limited thereto.

In addition, the first nitride layer 331 may include at least one pit 331p formed on an upper portion thereof. A surface of the at least one pit 331p may have a different crystal plane from the crystal plane of the upper surface of the first nitride layer 331. For example, the at least one pit 331p may be a V-pit having a substantially ‘V’-shaped cross-section. The at least one pit 331p may be obtained by controlling the growth conditions of the first nitride layer 331. By way of example, upon growth of the first nitride layer 331, the first nitride layer 331 may be three-dimensionally grown to form a semiconductor layer having a rougher surface by adjusting the growth conditions so as to have a higher vertical growth speed with respect to a lateral growth speed than that of the base layer 130.

As one method, when the first nitride layer 331 is grown at a lower temperature than a suitable temperature, at least one pit 331p can be formed on an upper surface of the first nitride layer 331. More specifically, referring to FIG. 19, the base layer 130 may be grown at a first temperature and the first nitride layer 331 may be grown at a second temperature. Here, when the first nitride layer 331 is grown at a third temperature higher than the second temperature, the first nitride layer 331 may have good morphology without substantial generation of the pits 331p. The second temperature may be higher than the first temperature by a temperature of greater than 0 to 150° C. or less. That is, a difference between the first temperature and the second temperature may be greater than 0 to 150° C. or less. As such, when the first nitride layer 331 is grown at the second temperature that is lower than a suitable growth temperature (third temperature), a portion of the first nitride layer can suffer from uneven crystallization in the growth direction due to lack of thermal energy and at least one pit 331p can be formed in the portion. For example, upon growth of the first nitride layer 331 formed of AlN on the base layer 130, the uppermost region of which is formed of GaN, GaN of the base layer 130 may be grown at a temperature of about 1,100° C. (first temperature) and AlN of the first nitride layer 331 may be grown at a temperature of about 1,200° C. (second temperature). Since the growth temperature (third temperature) capable of securing good surface morphology of AlN without substantial generation of pits is about 1,400° C., at least one pit 331p can be formed on the surface of the first nitride layer 331.

The first nitride layer 331 may be composed of multiple layers. In this structure, the first nitride layer 331 may include a pit generation layer and a pit expansion layer formed on the pit generation layer. The pit expansion layer is grown using an upper surface of the pit generation layer as a seed and the size of the pit 331p can increase with growth of the pit generation layer. The pit expansion layer may have a higher average lattice parameter than the pit expansion layer. The pit expansion layer may have a lower Al composition ratio than the pit generation layer. For example, the pit generation layer may be an AlN layer and the pit expansion layer may be an AlGaN layer. Accordingly, during growth of the pit expansion layer, compressive strain and compressive stress are continuously applied to the pit expansion layer in the horizontal direction, thereby causing expansion of the pit 331p in the horizontal direction. With the structure wherein the first nitride layer 331 includes the pit expansion layer, the light detection device can have further improved electrostatic discharge resistance by enlarging the size of the pit 331p.

As such, the first nitride layer 331 has relatively poor crystallinity due to growth at a relatively low temperature and includes at least one pit 331p, thereby blocking low electric current while allowing electric current generated by static electricity to pass through the at least one pit 331p. With this structure, the light detection device can have improved light detection efficiency and electrostatic discharge resistance. This will be described in more detail below.

Next, referring to FIG. 14, a second nitride layer 333 is formed on the first nitride layer 331. Accordingly, an ESD prevention layer 330 including the first nitride layer 331 and the second nitride layer 333 can be formed.

The second nitride layer 333 may be formed on the first nitride layer 331 by, for example, MOCVD and includes a nitride-based semiconductor such as (Al, Ga, In)N. Particularly, the second nitride layer 333 may include a nitride-based semiconductor having a lower Al composition ratio than the first nitride layer 331 and represented by, for example, Al_{y}Ga_{(1-y)}N(y<0.9). The second nitride layer 333 may be undoped. As the second nitride layer 333 formed of the nitride-based semiconductor having a lower Al composition ratio than the first nitride layer 331 is grown on the first nitride layer 331, it is possible to reduce stress and strain due to a difference in lattice parameter between the first nitride layer 331 and the light absorption layer 150.

Further, the second nitride layer 333 may be formed to fill the pits 331p of the first nitride layer 331. Furthermore, the second nitride layer 333 may include one or more defect concentrated portions 333d. The defect concentrated portions 333d may extend from at least some pits 331p. The pits 331p are regions having relatively poor crystallinity and a portion of a layer grown on the pits 331p has a high probability of generating defects such as lattice mismatch. Accordingly, a portion of the second nitride layer 333 grown on the pits 331p can have high density of dislocations, which can extend upwards during growth of the second nitride layer 333. Some of the defect concentrated portions 333d may extend to an upper surface of the second nitride layer 333 and other portion thereof may be interrupted inside the second nitride layer 333.

The second nitride layer 333 may have a sufficient thickness to fill the pits 331p of the first nitride layer 331 and to relieve stress and strain applied to the first nitride layer 331 while improving crystallinity thereof. Thus, the second nitride layer 333 may be thicker than the first nitride layer 331 and may have a thickness of, for example, 70 nm to 100 nm, without being limited thereto. The first nitride layer 331 may have a higher defect density than the second nitride layer 333.

The second nitride layer 333 may be formed of a nitride semiconductor having a smaller energy band gap than the first nitride layer 331, whereby a two-dimensional electron gas (2DEG) can be formed at an interface between the first nitride layer 331 and the second nitride layer 333. As shown in an enlarged sectional view of FIG. 15, the two-dimensional electron gas (2DEG) may be formed around at least part of the interface between the first and second nitride layers 331, 333 and may be formed inside the second nitride layer 333. The two-dimensional electron gas (2DEG) may be generated through formation of a potential well at the interface between the first nitride layer 331 and second nitride layer 333 by variation in energy band gap caused by a difference in Al composition ratio between the first nitride layer 331 and second nitride layer 333, spontaneous polarization, and piezoelectric polarization caused by a difference in lattice parameter therebetween. For example, in a structure wherein the first nitride layer 331 is formed of MN and the second nitride layer 333 is formed of AlGaN having an Al composition ratio of about 0.4, the two-dimensional electron gas (2DEG) can be formed at the interface therebetween. Such a two-dimensional electron gas (2DEG) can promote movement of electric current in the horizontal direction, thereby preventing low electric current (caused by reaction with visible light) passing through the interface between the first nitride layer 331 and the second nitride layer 333 from being transferred to the base layer 130.

Next, referring to FIG. 16, a light absorption layer 150 is formed on the second nitride layer 333.

The light absorption layer 150 may include a nitride semiconductor, and components and the composition ratio of the nitride semiconductor for the light absorption layer 150 may be set depending upon the wavelengths of light to be detected by the light detection device. For example, for fabrication of a light detection device configured to detect UV light in the UVA band, a light absorption layer 150 having a GaN layer or an InGaN layer may be grown, for fabrication of a light detection device configured to detect UV light in the UVB band, a light absorption layer 150 including an AlGaN layer having an Al composition ratio of 28% or less may be grown, and for fabrication of a light detection device configured to detect UV light in the UVC band UVC, a light absorption layer 150 including an AlGaN layer having an Al composition ratio of 28% to 50% may be grown.

Particularly, in this exemplary embodiment, the light absorption layer 150 may include an AlGaN layer having an Al composition ratio of 0.28 or more, specifically an AlGaN layer having an Al composition ratio of 0.4 or more. Accordingly, the light detection device has a light detection function with respect to light in the UVC band.

Furthermore, the light absorption layer 150 may be grown to a thickness of 0.1 μm or more, specifically a thickness of 0.1 μm to 0.5 μm. If the thickness of the light absorption layer 150 is less than 0.1 μm, the depletion region can expand to a portion under the light absorption layer 150, thereby deteriorating light detection efficiency and light detection accuracy. Preferably, the light absorption layer 150 has a thickness of 0.1 μm or more. On the other hand, during growth of the AlGaN layer having an Al composition ratio of 0.15 μm or more, if the thickness of the AlGaN layer is greater than 0.1 μm, there is a high probability of generating cracks in the AlGaN layer. On the other hand, according to this exemplary embodiment, the light detection device includes the first nitride layer 331 having an Al composition ratio of 0.9 or more, thereby effectively preventing generation of cracks in the light absorption layer 150 including the AlGaN layer having an Al composition ratio of 0.28 or more. Therefore, the present exemplary embodiment can provide a light detection device having a light detection function with respect to UV light in the UVC band and a method of fabricating the same.

Next, referring to FIG. 17, a partially exposed portion 100a of the base layer 130 is formed by partially removing the light absorption layer 150, the second nitride layer 333, and the first nitride layer 331. In addition, a portion of the base layer 130 under the exposed portion may be further removed in the thickness direction. Partial removal of the light absorption layer 150, the second nitride layer 333 and the first nitride layer 331 may be carried out through photolithography and etching, for example, dry etching.

Next, referring to FIG. 18, a Schottky junction layer 160 is formed on the light absorption layer 150. In addition, a second electrode 173 and a first electrode 171 may be further formed on the Schottky junction layer 160 and the exposed portion 100a of the base layer 130, respectively.

The Schottky junction layer 160 may be formed by deposition of a material including at least one of ITO, Ni, Co, Pt, W, Ti, Pd, Ru, Cr, and Au. The thickness of the Schottky junction layer 160 may be regulated by taking light transmission and Schottky characteristics into account, and may be, for example, 10 nm or less. The method of fabricating the light detection device may further include a cap layer (not shown) between the Schottky junction layer 160 and the light absorption layer 150. The cap layer may be formed by growing a p-type nitride semiconductor layer doped with a p-type dopant such as Mg. The cap layer may have a thickness of 100 nm or less, preferably 5 nm or less. The cap layer can improve the Schottky characteristics of the device.

Alternatively, the Schottky junction layer 160 may be formed before formation of the exposed region 100a of the base layer 130.

The first and second electrodes 171, 173 may be formed by deposition of a metallic material, followed by lift-off, and may be composed of multiple layers. For example, the first electrode 171 may be formed by stacking Cr/Ni/Au layers and the second electrode 173 may be formed by stacking Ni/Au layers.

As a result, a light detection device 105 as shown in FIG. 18 can be provided.

Next, referring to FIG. 18, the light detection device 105 will be described in more detail. However, repeated descriptions of the components described in description of the method of fabricating the light detection device with reference to FIG. 11 to FIG. 18 will be omitted.

Referring to FIG. 18, the light detection device 105 includes the base layer 130, the ESD prevention layer 330, the light absorption layer 150, and the Schottky junction layer 160. In addition, the light detection device 105 may further include the substrate 110, the buffer layer 120, the first electrode 171, and the second electrode 173. The ESD prevention layer 330 may include the first nitride layer 331 and the second nitride layer 333. The light detection device 105 according to this exemplary embodiment can perform light detection of UV light, particularly, UV light in the UVC band. Further, the light detection device has good light detection efficiency and good electrostatic discharge resistance. Hereinafter, this will be described in more detail.

When the light detection device 105 is illuminated, the light absorption layer 150 absorbs the light reaching the light detection device. In the structure wherein the Schottky junction layer 160 is formed on the light absorption layer 150, an electron-hole separation region, that is, a depletion region, is formed between interfaces. When electric current is generated by electrons generated by the light, the light detection device measures the electric current, thereby performing light detection. For example, when the light detection device is a UV light detection device, an ideal UV light detection device has an infinite UV-to-visible light rejection ratio. However, in a typical UV light detection device, electric current is generated through reaction of the light absorption layer with visible light due to inherent defects of the light absorption layer. Thus, the typical light detection device has a UV-to-visible rejection ratio of 10³ or less, causing failure in detection of light.

Conversely, in the light detection device 105 according to the above exemplary embodiments, minute electric current, that is, electrons generating the minute electric current, generated in the light absorption layer 150 by visible light are captured by the first nitride layer 331, thereby preventing operation of the light detection device by visible light as much as possible. As described above, the first nitride layer 331 is grown at a relatively low temperature and thus has a higher defect density than the light absorption layer 150. The amount of electrons generated by visible light is much smaller than the amount of electrons generated by UV light, whereby the electrons can be captured by defects present in the first nitride layer 331. On the other hand, the amount of electrons generated by irradiation of the light absorption layer 150 with UV light (particularly, UV light in the UVC band) is much greater than the amount of electrons generated by visible light, and thus can move towards the base layer 130 without being captured by the first nitride layer 331.

Furthermore, the two-dimensional electron gas (2DEG) can be formed at the interface between the first nitride layer 331 and the second nitride layer 333, and can promote movement of electric current in the horizontal direction. As described above, since electrons generated in the light absorption layer 150 by visible light have too low energy to pass through the two-dimensional electron gas (2DEG) in the vertical direction, most electrons generated by visible light fail to pass from the second nitride layer 333 to the first nitride layer 331.

Therefore, the light detection device 105 according to this exemplary embodiment exhibits very low reactivity with visible light and thus can have a high UV-to-visible rejection ratio. Particularly, the light detection device according to this exemplary embodiment has a UV-to-visible rejection ratio of 10⁴ or more.

In addition, the first nitride layer 331 includes at least one pit 331p and the second nitride layer 333 may include a defect concentrated portion 333d extending from at least some pits 331p. Since the pits 331p and the defect concentrated portion 333d have higher energy than other portions, the pits 331p and the defect concentrated portion 333d can act as paths of high electric current generated by electrostatic discharge. Accordingly, in the case where high electric current is generated in the light detection device 105 by electrostatic discharge, the high electric current can easily flow through the pits 331p and/or the defect concentrated portion 333d, thereby preventing failure of semiconductor layers due to high electric current. That is, the light detection device 105 includes the ESD prevention layer 330, thereby exhibiting high electrostatic discharge resistance.

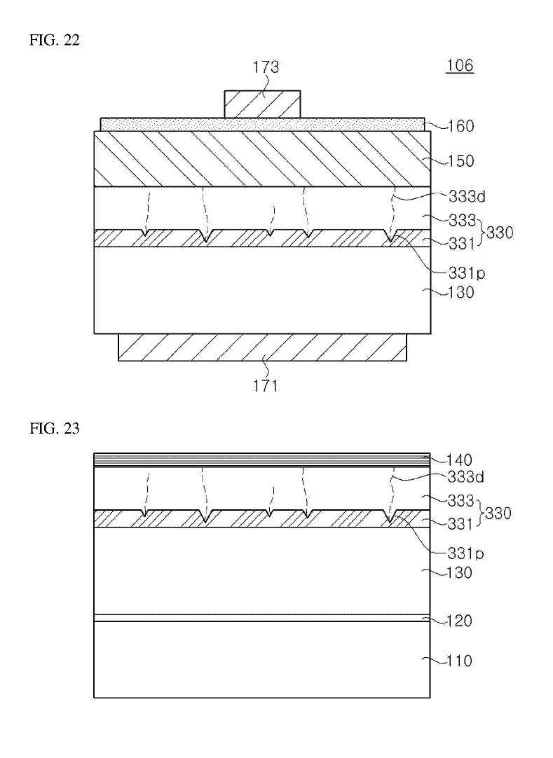

FIG. 20 to FIG. 22 are sectional views of a light detection device according to yet another exemplary embodiment of the present disclosure and a method of fabricating the same.

A light detection device 106 according to this exemplary embodiment is different from the light detection device 105 of FIG. 11 to FIG. 19 in that electrodes 171, 173 are vertically disposed. The following description will be mainly given of different features of the light detection device 106 according to this exemplary embodiment and a method of fabricating the same.

First, the method of fabricating the light detection device 106 according to this exemplary embodiment includes the processes described with reference to FIG. 11 to FIG. 16. FIG. 20 illustrates a process performed after the process shown in FIG. 16.

Referring to FIG. 20, the substrate 110 is separated from the base layer 130. The substrate 110 is separated and removed from the first nitride layer 331 by at least one method selected from among laser lift-off, chemical lift-off, thermal lift-off, and stress lift-off.

Next, referring to FIG. 21 and FIG. 22, a Schottky junction layer 160 is formed on a light absorption layer 333, and a second electrode 173 and a first electrode 171 are formed on an upper surface of the Schottky junction layer 160 and a lower surface of the base layer 130, respectively, thereby providing the light detection device 106 as shown in FIG. 22. The light detection device 106 according to this exemplary embodiment may include the first and second electrodes 171, 173 vertically arranged.

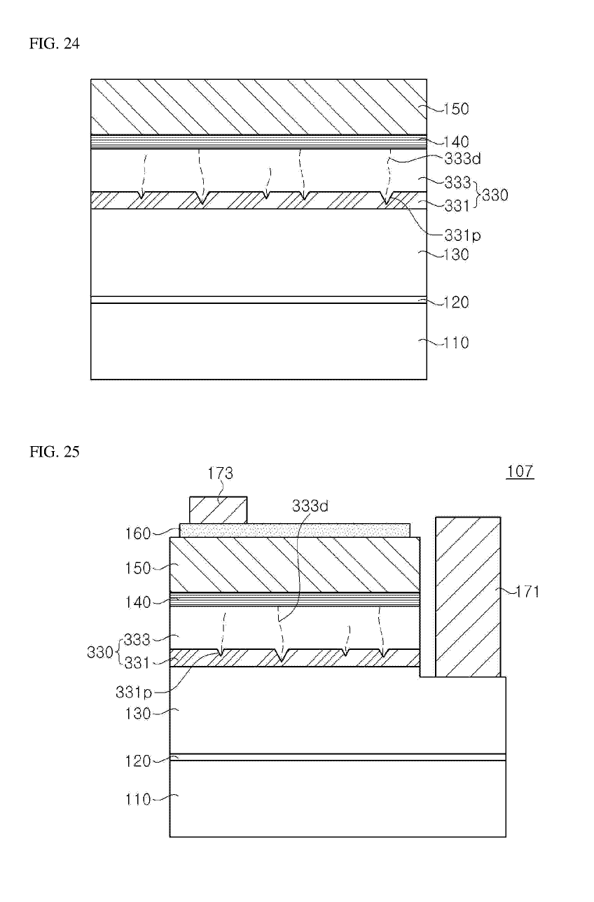

FIG. 23 to FIG. 25 are sectional views of a light detection device according to yet another exemplary embodiment of the present disclosure and a method of fabricating the same.

Unlike the light detection device 105 of FIG. 11 to FIG. 19, a light detection device 107 according to this exemplary embodiment further includes a low current blocking layer 190. The following description will be mainly given of different features of the light detection device 107 according to this exemplary embodiment and a method of fabricating the same.

First, the method of fabricating the light detection device 107 according to this exemplary embodiment includes the processes described with reference to FIG. 11 to FIG. 15. FIG. 23 illustrates a process performed after the process shown in FIG. 15.

Referring to FIG. 23, the low current blocking layer 190 is formed on the second nitride layer 333.

The low current blocking layer 190 may include a multilayer structure layer, which may be formed by repeatedly stacking binary to quaternary nitride layers including (Al, In, Ga)N. The multilayer structure layer may include at least two nitride layers having different composition ratios. The nitride layers of the multilayer structure layer may be determined depending upon the composition of the nitride layer of the light absorption layer 150. For example, for the light absorption layer 150 including an AlGaN layer, the multilayer structure layer may have a stack structure of AlN/AlGaN layers or AlGaN/AlGaN layers. The stack structure may be formed by stacking 3 to 10 pairs of nitride layers and the low current blocking layer may have a thickness of 10 nm to 100 nm. In addition, the low current blocking layer 190 may have a higher defect density than the light absorption layer 150. This can be obtained by controlling the growth conditions of the low current blocking layer 190. For example, the low current blocking layer 190 having a high defect density can be formed by growing the low current blocking layer 190 at a lower temperature than the light absorption layer 150.

Each of the at least two nitride layers having different composition ratios may be grown to a thickness of 5 nm to 10 nm and may be grown to have a different composition ratio through adjustment of flow rates of source gases. Alternatively, the at least two nitride layers having different composition ratios may be formed by stacking nitride layers under different pressures in the growth chamber while maintaining other conditions including the flow rates of source gases.

For example, in order to form a multilayer structure layer having a structure wherein AlₓGa₍₁₋ₓ₎N layers and Al_{y}Ga_{(1-y)}N layers are repeatedly stacked one above another, the AlₓGa₍₁₋ₓ₎N layers are grown at a pressure of about 100 Torr and the Al_{y}Ga_{(1-y)}N layers are grown at a pressure of about 400 Torr. Under the same growth conditions excluding pressure, the AlₓGa₍₁₋ₓ₎N layers grown at a lower pressure can have a higher Al composition ratio than the Al_{y}Ga_{(1-y)}N layers grown at a higher pressure. As such, the low current blocking layer 190 including the multilayer structure layer formed through growth at different pressures can improve crystallinity of the light absorption layer 150 formed on the low current blocking layer 190 by preventing generation and propagation of dislocations during growth. In addition, since the nitride layers having different composition ratios are repeatedly stacked one above another through growth at different pressures, the occurrence of cracking in the light absorption layer 150 can be prevented by relieving stress caused by a difference in lattice parameter. Furthermore, the nitride layers are grown by changing pressure while maintaining the flow rates of source gases, thereby enabling easy formation of the low current blocking layer 190.

Referring to FIG. 24, the light absorption layer 150 is formed on the low current blocking layer 190. Next, referring to FIG. 25, a Schottky junction layer 160 is formed on the light absorption layer 150, and a second electrode 173 and a first electrode 171 are formed on the Schottky junction layer 160 and the exposed region of the base layer 130, respectively, thereby providing the light detection device 107 as shown in FIG. 25. The low current blocking layer 190 has a higher defect density than the light absorption layer 150 and thus can block flow of electrons generated by reaction between the light absorption layer 150 and visible light. Blocking of electrons by the low current blocking layer 190 can be achieved by a similar mechanism to blocking of electrons generated in the first nitride layer 331 by visible light. As such, the low current blocking layer 190 and the first nitride layer 331 block electrons generated by reaction with visible light from moving into the base layer 130, thereby providing a light detection device having further improved light detection efficiency.

Although some examples and exemplary embodiments have been described herein, it should be understood by those skilled in the art that these embodiments are given by way of illustration only, and that various modifications, variations and alterations can be made without departing from the spirit and scope of the present disclosure.

1. A light detection device comprising:
a base layer;
an electrostatic discharge (ESD) prevention layer disposed on the base layer and including an undoped nitride-based semiconductor material;
a light absorption layer disposed on the ESD prevention layer;
a Schottky junction layer disposed on the light absorption layer; and
a first electrode and a second electrode electrically connected to the base layer and the Schottky junction layer, respectively,
wherein the ESD prevention layer has a lower average n-type dopant concentration than the base layer.

2. The light detection device of claim 1, wherein the ESD prevention layer includes at least one undoped nitride-based semiconductor layer, the at least one undoped nitride-based semiconductor layer having a thickness of 300 nm to 400 nm.

3. The light detection device of claim 1, further including:
a low current blocking layer disposed between the ESD prevention layer and the light absorption layer, the low current blocking layer including a multilayered structure.

4. The light detection device of claim 3, wherein the multilayered structure include layers forming an interface between the layers, the interface having a greater band gap than each of the layers of the multilayered structure.

5. The light detection device of claim 1, wherein the ESD prevention layer includes a doped region.

6. The light detection device of claim 5, wherein the doped region includes a first doped region, a second doped region disposed on the first doped region, and a third doped region disposed on the second doped region, and wherein the second doped region has a higher doping concentration than the first doped region, and the third doped region has a higher doping concentration than the second doped region.

7. The light detection device of claim 6, wherein the first doped region adjoins the second doped region and the second doped region adjoins the third doped region.

8. The light detection device of claim 6, wherein the first to third doped regions include n-type dopants and at least one of the first to third doped regions has a concentration of the n-type dopants gradually increasing or decreasing towards the light absorption layer.

9. The light detection device of claim 5, wherein the doped region includes at least one n-type dopant shock region.

10. The light detection device of claim 5, wherein the undoped nitride-based semiconductor material is placed on an upper surface and a lower surface of the doped region.

11. The light detection device of claim 3, wherein the undoped nitride-based semiconductor material of the ESD prevention layer adjoins at least one of the low current blocking layer and the base layer.

12. The light detection device of claim 1, wherein the light absorption layer includes at least one of AlGaN and AlInGaN.

13. The light detection device of claim 3, wherein the multilayered structure of the low current blocking layer includes a super lattice structure in which AlₓGa₍₁₋ₓ₎N layers and Al_{y}Ga_{(1-y)}N layers (x≠y) are repeatedly stacked one above another.

14. The light detection device of claim 1, wherein the low current blocking layer has a higher defect density than the light absorption layer.

15. The light detection device of claim 1, further including:
a substrate disposed under the base layer,
wherein the second electrode is placed on the Schottky-junction layer and the first electrode is placed on the base layer to be electrically connected thereto.

16. The light detection device of claim 1, wherein the light detection device is flip-bonded to a secondary substrate such that the light absorption layer and the secondary substrate are sequentially disposed in a downward direction further away from the base layer.

17. The light detection device of claim 1, wherein the second electrode is disposed under a lower surface of the Schottky-junction layer, and the first electrode is disposed on an upper surface of the base layer.

18. The light detection device of claim 16, wherein the base layer has a greater energy band gap than the light absorption layer.

19. The light detection device of claim 17, wherein the base layer has a greater energy band gap than the light absorption layer.

20. A light detection device comprising:
a base layer including a nitride-based semiconductor material;
an ESD prevention layer disposed on the base layer;
a light absorption layer disposed on the ESD prevention layer and including an Al-containing nitride-based semiconductor layer; and
a Schottky junction layer disposed on the light absorption layer,
wherein the ESD prevention layer includes:
a first nitride layer disposed on the base layer and including a nitride-based semiconductor material having an Al composition ratio of 0.9 or more; and
a second nitride layer disposed on the first nitride layer and including a nitride-based semiconductor material having a lower Al composition ratio than the first nitride layer,
wherein the first nitride layer includes a pit formed on an upper portion thereof, and the second nitride layer fills the pit.

21. The light detection device of claim 20, wherein the light absorption layer includes AlGaN having an Al composition ratio of 0.28 or more.

22. The light detection device of claim 21, wherein the light absorption layer includes AlGaN having an Al composition ratio of 0.4 or more.

23. The light detection device of claim 20, wherein the second nitride layer includes a defect concentrated portion extending from the pit.

24. The light detection device of claim 20, wherein the first nitride layer includes AlN and the second nitride layer includes AlGaN.

25. The light detection device of claim 24, wherein the base layer includes a GaN layer.

26. The light detection device of claim 20, further including:
a low current blocking layer disposed between the second nitride layer and the light absorption layer, the low current blocking layer including a multilayered structure.

27. The light detection device of claim 20, further including:
a first electrode and a second electrode electrically connected to the base layer and the Schottky-junction layer, respectively.

28. A light detection device comprising:
a base layer including a nitride-based semiconductor material;
an ESD prevention layer disposed on the base layer;
a light absorption layer disposed on the second nitride layer and including an Al-containing nitride-based semiconductor layer; and
a Schottky junction layer disposed on the light absorption layer,
wherein the ESD prevention layer includes:
a first nitride layer disposed on the base layer and including a nitride-based semiconductor material having an Al composition ratio of 0.9 or more; and
a second nitride layer disposed on the first nitride layer and including a nitride-based semiconductor material having a lower Al composition ratio than the first nitride layer, and
wherein the first nitride layer includes a pit formed on an upper portion thereof, and the first nitride layer has a higher defect density than the second nitride layer.

29. The light detection device of claim 28, wherein the second nitride layer fills the pit and includes a defect concentrated portion extending from the pit.

30. A method of fabricating a light detection device, comprising:
forming a base layer including a nitride-based semiconductor material on a substrate;
forming a first nitride layer on the base layer to include a nitride-based semiconductor material having an Al composition ratio of 0.9 or more, the first nitride layer including a pit;
forming a second nitride layer on the first nitride layer to include a nitride-based semiconductor material having a lower Al composition ratio than the first nitride layer;
forming a light absorption layer on the second nitride layer to include an Al-containing nitride-based semiconductor material; and
forming a Schottky junction layer on the light absorption layer.

31. The method of fabricating a light detection device of claim 30, wherein the base layer is grown at a first temperature, the first nitride layer is grown at a second temperature, and a difference between the first temperature and the second temperature is greater than 0 and 150° C. or less.

32. The method of fabricating a light detection device of claim 30, wherein the light absorption layer includes AlGaN having an Al composition ratio of 0.4 or more.

33. The method of fabricating a light detection device of claim 30, wherein forming the second nitride layer includes forming a defect concentrated portion extending from the pit.

34. The method of fabricating a light detection device of claim 30, wherein the first nitride layer includes AlN and the second nitride layer includes AlGaN.

35. The method of fabricating a light detection device of claim 30, further including:
forming a low current blocking layer disposed between the second nitride layer and the light absorption layer the low current blocking layer including a multilayered structure.

36. The light detection device of claim 6, wherein the first to third doped regions include n-type dopants and-at least one of the first to third doped regions has a concentration of the n-type dopants irregularly increasing or decreasing towards the light absorption layer.
